(19) United States
(12) Patent Application Publication
(10) Pub. No.: US 2009/0162716 A1
(43) Pub. Date: Jun. 25, 2009

(54) Method of Manufacturing Fuel Cell

(75) Inventor: Satoshi Aoyama, Susono-shi (JP)

Correspondence Address: OLIFF & BERRIDGE, PLC, P.O. BOX 320850, ALEXANDRIA, VA, 22320-4850, US

(73) Assignee: TOYOTA JIDOSHA KABUSHIKI KAISHA, Toyota-shi (JP)

(21) Appl. No.: 11/992,138

(22) PCT Filed: Sep. 26, 2006
(86) PCT No.: PCT/JP2006/319648

§ 371 Date: Mar. 17, 2008

(30) Foreign Application Priority Data
Oct. 6, 2005 (JP) 2005-294059

(51) Int. Cl. H01M 8/10; B05D 5/12; C23C 14/34

(52) U.S. Cl. 429/30; 427/115; 204/192.12

(57) ABSTRACT

A method of manufacturing a fuel cell is comprising: a hydrogen permeable membrane forming step of forming a second hydrogen permeable membrane on a first hydrogen permeable membrane; and an electrolyte layer forming step of forming an electrolyte layer on the second hydrogen permeable membrane. In this case, it is possible to form the electrolyte layer having few defects. Adhesiveness is therefore improved between the electrolyte layer and the second hydrogen permeable membrane. Accordingly, a separation is restrained between the electrolyte layer and the second hydrogen permeable membrane.

### TECHNICAL FIELD

This invention generally relates to a method of manufacturing a fuel cell.

### BACKGROUND ART

In general, a fuel cell is a device that obtains electrical power from fuel, hydrogen and oxygen. Fuel cells are being widely developed as an energy supply device because fuel cells are environmentally superior and can achieve high energy efficiency.

There are some types of fuel cells including a solid electrolyte such as a polymer electrolyte fuel cell, a solid-oxide fuel cell, and a hydrogen permeable membrane fuel cell (HMFC). Here, the hydrogen permeable membrane fuel cell has a dense hydrogen permeable membrane. The dense hydrogen permeable membrane is composed of a metal having hydrogen permeability, and acts as an anode. The hydrogen permeable membrane fuel cell has a structure in which an electrolyte having proton conductivity is deposited on the hydrogen permeable membrane. Some hydrogen provided to the hydrogen permeable membrane is converted into protons with catalyst reaction. The protons are conducted in the electrolyte having proton conductivity, react with oxygen provided at a cathode, and electrical power is thus generated, as disclosed in Patent Document 1.

A noble metal such as palladium is used as the hydrogen permeable membrane for the hydrogen permeable membrane fuel cell. It is therefore necessary to reduce a thickness of the hydrogen permeable membrane as much as possible in order to reduce a cost.

### Patent Document 1: Japanese Patent Application Publication No. 2004-146337

### DISCLOSURE OF THE INVENTION

### Problems to be Solved by the Invention

However, an air bubble in the hydrogen permeable membrane may be exposed when the thickness of the hydrogen permeable membrane is reduced. Concavity and convexity may be formed on a surface of the hydrogen permeable membrane. In this case, the hydrogen permeable membrane may be separated from the electrolyte layer because of the concavity and the convexity.

An object of the present invention is to provide a method of manufacturing a fuel cell that restrains a separation between the hydrogen permeable membrane and the electrolyte layer.

### Means for Solving the Problems

A method of manufacturing a fuel cell in accordance with the present invention is characterized by comprising a hydrogen permeable membrane forming step of forming a second hydrogen permeable membrane on a first hydrogen permeable membrane, and an electrolyte layer forming step of forming an electrolyte layer on the second hydrogen permeable membrane. With the method of manufacturing the fuel cell in accordance with the present invention, the second hydrogen permeable membrane is formed on the first hydrogen permeable membrane, and the electrolyte layer is formed on the second electrolyte layer. In this case, a concave portion formed on a surface of the first hydrogen permeable membrane may be filled with the second hydrogen permeable membrane. A surface of the second hydrogen permeable membrane may be smoothed because the second hydrogen permeable membrane is formed on the filled surface of the first hydrogen permeable membrane. And the electrolyte layer having few defects may be formed. Adhesiveness is therefore improved between the electrolyte layer and the second hydrogen permeable membrane. And a separation is restrained between the electrolyte layer and the second hydrogen permeable membrane.

The first hydrogen permeable membrane may be a hydrogen permeable metal membrane manufactured with a melting and rolling method or a liquid quenching method. In this case, a plurality of concave portions are formed on the surface of the first hydrogen permeable membrane. The second hydrogen permeable membrane, therefore, may fill the concave portions of the first hydrogen permeable membrane.

The method may further include a jointing step of jointing a supporter to the first hydrogen permeable membrane on the opposite side of the second hydrogen permeable membrane before the hydrogen permeable membrane formation step. In this case, the first hydrogen permeable membrane may be jointed to the supporter. Although there is a case where concave portions and convex portions may be formed on the surface of the first hydrogen permeable membrane during the jointing step, the second hydrogen permeable membrane may fill the concave portions. The jointing step may be a jointing step with a cladding.

The method may further include a polishing step of polishing the second hydrogen permeable membrane on an opposite side of the first hydrogen permeable membrane before the electrolyte layer forming step after the hydrogen permeable membrane forming step. In this case, the surface of the second hydrogen permeable membrane may be more smoothed. And it is possible to reduce the thickness of the second permeable membrane. It is therefore possible to downsize the fuel cell in accordance with the present invention.

Hardness of the second hydrogen permeable membrane may be higher than that of the first hydrogen permeable membrane. In this case, polishing mark is hard to be formed on the surface of the second hydrogen permeable membrane during a polishing step of the surface of the second hydrogen permeable membrane. The surface of the second hydrogen permeable membrane, therefore, may be more smoothed. It is, of course, not limited to the case, when the second hydrogen permeable membrane is not polished.

The hydrogen permeable membrane forming step may be a forming step with a PVD method, a CVD method, a sputtering method, a plating method or a sol-gel method. In this case, few air bubbles are not formed in the second hydrogen permeable membrane. The surface of the second hydrogen permeable membrane, therefore, may be smoothed. Few concave portions and few convex portions may be formed on the surface of the second hydrogen permeable membrane, even if the second hydrogen permeable membrane is subjected to a pressure in a later step. And the hydrogen permeable membrane forming step may be a step of forming a metal layer on the first hydrogen permeable membrane and forming the second hydrogen permeable membrane that is an alloy layer composed of the metal layer and the first hydrogen permeable membrane by subjecting the metal layer to a thermal treatment.

### Effects of the Invention

According to the present invention, a separation is restrained between en electrolyte layer and a hydrogen permeable membrane.

### BRIEF DESCRIPTION OF THE DRAWINGS

FIG. 1A through FIG. 1F illustrate a flow diagram of manufacturing a fuel cell in accordance with a first embodiment of the present invention;

FIG. 2A through FIG. 2G illustrate a flow diagram of manufacturing a fuel cell in accordance with a second embodiment of the present invention; and

FIG. 3A and FIG. 3B illustrate another flow diagram of manufacturing a fuel cell in accordance with the second embodiment.

### BEST MODES FOR CARRYING OUT THE INVENTION

A description will be given of best modes for carrying out the present invention.

### First Embodiment

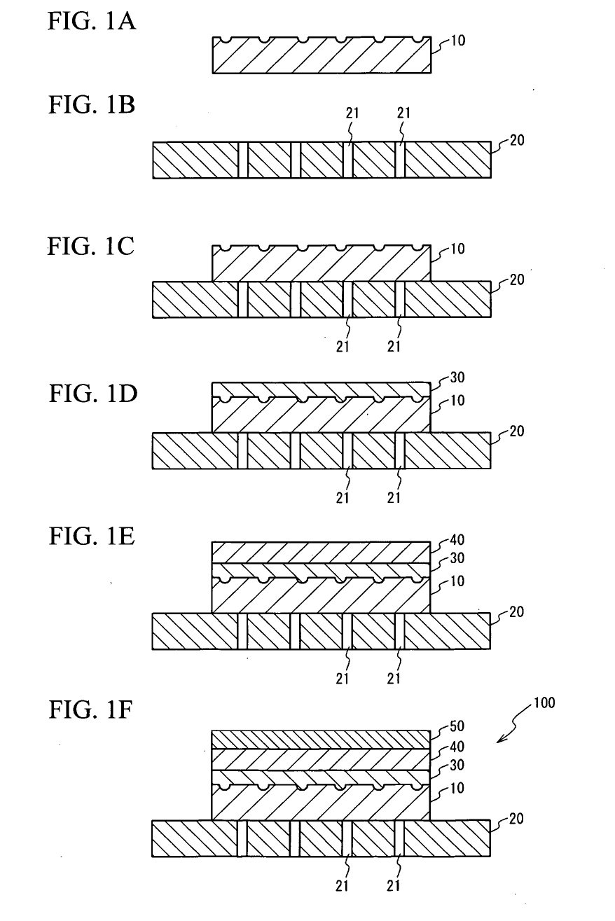

FIG. 1A through FIG. 1F illustrate a manufacturing flow diagram of a fuel cell 100 in accordance with a first embodiment of the present invention. As shown in FIG. 1A, a first hydrogen permeable membrane 10 is provided. The first hydrogen permeable membrane 10 is composed of a hydrogen permeable metal. A metal composing the first hydrogen permeable membrane 10 is such as Pd, Ta, Zr, Nb, V, an alloy including them or the like. For example, the first hydrogen permeable membrane 10 has a thickness of approximately 20 μm.

The first hydrogen permeable membrane 10 may be formed with a melting and rolling process. The first hydrogen permeable membrane 10 may be formed with a liquid quenching process. The melting and rolling process is a manufacturing method including a melting process such as ingot melting and a rolling process.

Here, concave portions having a depth of approximately 1 μm may be formed on a surface of the first hydrogen permeable membrane 10, because a melted and rolled material includes air bubble not to be removed during the melting process of an ingot, and a liquid-quenched material includes air bubble not to be removed during the melting process of a metal in a liquid quenching method.

Next, as shown in FIG. 1B, a supporter 20 is provided. The supporter 20 is, for example, composed of a metal such as stainless steel. The supporter 20 has a thickness of approximately 50 μm to 500 μm. A plurality of through holes 21 are formed in the supporter 20 in order to provide hydrogen to the first hydrogen permeable membrane 10. Then, as shown in FIG. 1C, the first hydrogen permeable membrane 10 is jointed to the supporter 20 with a cladding. In this case, another concave portion and convex portion may be formed on the surface of the first hydrogen permeable membrane 10.

Next, as shown in FIG. 1D, a second hydrogen permeable membrane 30 is formed on the first hydrogen permeable membrane 10 on an opposite side of the supporter 20. The second hydrogen permeable membrane 30 may be formed with a PVD method, a CVD method, a sputtering method, a plating method, or a sol-gel method. In this case, air bubble may not be included in the second hydrogen permeable membrane 30. This results in smoothing the surface of the second hydrogen permeable membrane 30. The second hydrogen permeable membrane 30 has a thickness of approximately 5 μm. In this case, the concave portion formed on the first hydrogen permeable membrane 10 may be filled.

Few concave portions and few convex portions are formed on the surface of the second hydrogen permeable membrane 30 even if the second hydrogen permeable membrane 30 is subjected to a high pressure in a latter process, because the formation of the air bubble is restrained in the second hydrogen permeable membrane 30 in the above-mentioned forming method.

A metal composing the second hydrogen permeable membrane 30 is such as Pd, Ta, Zr, V, an alloy including them or the like. Pd-based alloy may be such as Pd—Ag, Pd—Au, Pd—Pt, or Pd—Cu. V-based alloy may be V—Ni, V—Cr, or V—No—Cr. It is preferable that the second hydrogen permeable membrane 30 is composed of Pd-based alloy or Zr-based alloy, because hydrogen dissociation of the second hydrogen-permeable membrane 30 is increased.

Then, as shown in FIG. 1E, an electrolyte layer 40 having proton conductivity is formed on the second hydrogen permeable membrane 30 on an opposite side of the first hydrogen permeable membrane 10 with a sputtering method. In this case, the electrolyte layer 40 includes few defects because few concave portions and few convex portions are formed on the surface of the second hydrogen permeable membrane 30. Adhesiveness is therefore improved between the electrolyte layer 40 and the second hydrogen permeable membrane 30. It is therefore possible to restrain a separation between the second hydrogen permeable membrane 30 and the electrolyte layer 40.

Next, as shown in FIG. 1F, a cathode 50 is formed on the electrolyte layer 40 on an opposite side of the second hydrogen permeable membrane 30 with a sputtering method. With the processes, the fuel cell 100 is fabricated. The first hydrogen permeable membrane 10 may not be jointed to the supporter 20, although the embodiment includes the process of jointing the first hydrogen permeable membrane 10 to the supporter 20. This is because it is not necessary to support the first hydrogen permeable membrane 10 if the first hydrogen permeable membrane 10 has sufficient strength.

Next, a description will be given of an operation of the fuel cell 100. A fuel gas including hydrogen is provided to the first hydrogen permeable membrane 10 via the through holes 21 of the supporter 20. Some hydrogen in the fuel gas passes through the first hydrogen permeable membrane 10 and the second hydrogen permeable membrane 30 and gets to the electrolyte layer 40. The hydrogen is converted into protons and electrons at the electrolyte layer 40. The protons are conducted in the electrolyte layer 40, and get to the cathode 50. It is restrained that the hydrogen in the fuel passes through the electrolyte layer 40 and gets to the cathode 50, because the electrolyte layer 40 has few defects. It is therefore possible to restrain a failure of power generation of the fuel cell 100.

On the other hand, an oxidant gas including oxygen is provided to the cathode 50. The protons react with oxygen in the oxidant gas provided to the cathode 50. Water and electrical power are thus generated. The generated electrical power is collected via a separator not shown. With the operations, the fuel cell 100 generates electrical power.

### Second Embodiment

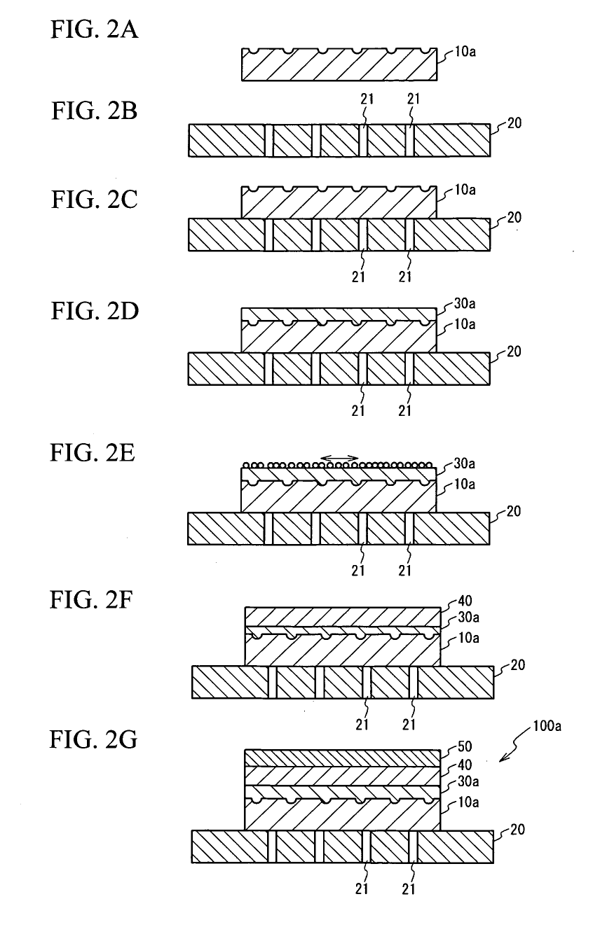

A description will be given of a manufacturing method of a fuel cell 100a in accordance with a second embodiment of the present invention. FIG. 2A through FIG. 2G illustrate a manufacturing flow diagram of the fuel cell 100a. The components having the same reference numerals are made of the same material as in the first embodiment.

As shown in FIG. 2A, a first hydrogen permeable membrane 10a is provided. The first hydrogen permeable membrane 10a is composed of a hydrogen permeable metal such as palladium alloy. In the embodiment, the first hydrogen permeable membrane 10 is composed of substantial pure palladium. Here, the substantially pure palladium is a palladium having a purity of 99.9%.

The first hydrogen permeable membrane 10a has a thickness of approximately 80 μm. The first hydrogen permeable membrane 10a may be formed with the melting and rolling process. The first hydrogen permeable membrane 10a may be formed with the liquid quenching process. Next, as shown in FIG. 2B, the supporter 20 is provided. Then, as shown in FIG. 2C, the first hydrogen permeable membrane 10a is jointed to the supporter 20 with the cladding.

Next, as shown in FIG. 2D, a second hydrogen permeable membrane 30a is formed on the first hydrogen permeable membrane 10a on an opposite side of the supporter 20. The second hydrogen permeable membrane 30a may be formed with the PVD method, the CVD method, the sputtering method, the plating method, or the sol-gel method. The second hydrogen permeable membrane 30a has a thickness of approximately 5 μm. The second hydrogen permeable membrane 30a is composed of palladium alloy having hardness (Vickers hardness) higher than that of the first hydrogen permeable membrane 10a. Table 1 shows examples of the second hydrogen permeable membrane 30a.

TABLE 1

| Composition(weight %) | Vickers Hardness |
|---|---|
| Pd | 45 |
| Pd77%Ag23% | 90 |
| Pd76%Pt24% | 55 |
| Pd60%Cu40% | 170 |
| Pd86%Ni14% | 160 |
| Pd89%Gd11% | 250 |
| Pd70%Au30% | 85 |
| Pd45%Au55% | 90 |
| Pd65%Au30%Rh5% | 100 |
| Pd70%Ag25%Rh5% | 130 |

Then, as shown in FIG. 2E, the second hydrogen permeable membrane 30a is polished by approximately 3 μm with liquid including aluminum paste, silica paste or the like. In this case, polishing mark is hard to be formed on the surface of the second hydrogen permeable membrane 30a, because the second hydrogen permeable membrane 30a has high hardness. A concave portion and a convex portion are hard to be formed on the polished second hydrogen permeable membrane 30a, because the formation of air bubble is restrained in the second hydrogen permeable membrane 30a in the above-mentioned forming method. This results in improvement of smoothness of the surface of the second hydrogen permeable membrane 30a. And it is possible to reduce the thickness of the second hydrogen permeable membrane 30a with polishing. It is therefore possible to reduce the thickness of the fuel cell 100a.

Next, as shown in FIG. 2F, the electrolyte layer 40 having proton conductivity is formed with the sputtering method or the like. In this case, the electrolyte layer 40 having few defects may be formed because the surface of the second hydrogen permeable membrane 30a has few concave portions and few convex portions. The adhesiveness is therefore increased between the electrolyte layer 40 and the second hydrogen permeable membrane 30a. Accordingly a separation is restrained between the second hydrogen permeable membrane 30a and the electrolyte layer 40. Next, as shown in FIG. 2G, the cathode 50 is formed on the electrolyte layer 40 on an opposite side of the second hydrogen permeable membrane 30a with the sputtering method or the like. With the processes, the fuel cell 100a is fabricated.

The first hydrogen permeable membrane 10a may be composed of other than the substantially pure palladium, although the first hydrogen permeable membrane 10a is composed of the substantially pure palladium. Any hydrogen permeable material can be used as the first hydrogen permeable membrane 10a.

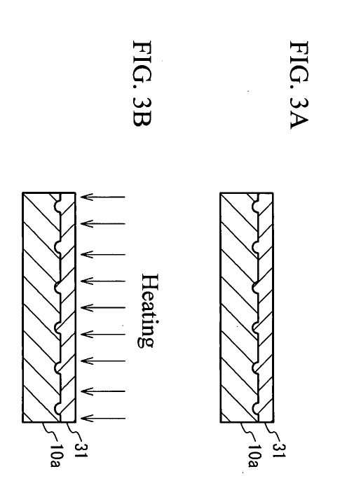

The formation method of the second hydrogen permeable membrane 30a is not limited to the method shown in FIG. 2D. The second hydrogen permeable membrane 30a may be formed in a method shown in FIG. 3A and FIG. 3B. A description will be given of the method. As shown in FIG. 3A, a metal layer 31 is formed on the first hydrogen permeable membrane 10a with the PVD method, the CVD method, the sputtering method, the plating method or the sol-gel method. The metal layer 31 is composed of a metal that has hardness higher than that of the first hydrogen permeable membrane 10a after being alloyed with the metal composing the first hydrogen permeable membrane 10a.

Next, as shown in FIG. 3B, the metal layer 31 and the second hydrogen permeable membrane 30a are subjected to a thermal treatment. This results in alloying the metal composing the metal layer 31 and the metal composing the second hydrogen permeable membrane 30a. And the metal layer 31 converted into the second hydrogen permeable membrane 30a. The effect of the second embodiment is obtained if the second hydrogen permeable membrane 30a is formed in the method.

1. A method of manufacturing a fuel cell comprising:
a hydrogen permeable membrane forming step of forming a second hydrogen permeable membrane on a first hydrogen permeable membrane; and
an electrolyte layer forming step of forming an electrolyte layer on the second hydrogen permeable membrane.

2. The method as claimed in claim 1, wherein the first hydrogen permeable membrane is a hydrogen permeable metal membrane manufactured with a melting and rolling method or a liquid quenching method.

3. The method as claimed in claim 1, further comprising a jointing step of jointing a supporter to the first hydrogen permeable membrane on an opposite side of the second hydrogen permeable membrane before the hydrogen permeable membrane forming step.

4. The method as claimed in claim 3, wherein the jointing step is a jointing step with a cladding.

5. The method as claimed in claim 1, further comprising a polishing step of polishing the second hydrogen permeable membrane on an opposite side of the first hydrogen permeable membrane before the electrolyte layer forming step after the hydrogen permeable membrane forming step.

6. The method as claimed in claim 1, wherein hardness of the second hydrogen permeable membrane is higher than that of the first hydrogen permeable membrane.

7. The method as claimed in claim 1, wherein the hydrogen permeable membrane forming step is a forming step with a PVD method, a CVD method, a sputtering method, a plating method or a sol-gel method.

8. The method as claimed in claim 1, wherein the hydrogen permeable membrane forming step is a step of forming a metal layer on the first hydrogen permeable membrane and forming the second hydrogen permeable membrane that is an alloy layer composed of the metal layer and the first hydrogen permeable membrane by subjecting the metal layer to a thermal treatment.

9. A fuel cell comprising:
a first hydrogen permeable membrane;
a second hydrogen permeable membrane that is formed on the first hydrogen permeable membrane; and
an electrolyte layer that is formed on the second hydrogen permeable membrane.

10. The fuel cell as claimed in claim 9, wherein the first hydrogen permeable membrane is a hydrogen permeable metal membrane manufactured with a melting and rolling method or a liquid quenching method.

11. The fuel cell as claimed in claim 9, wherein hardness of the second hydrogen permeable membrane is higher than that of the first hydrogen permeable membrane.

12. The fuel cell as claimed in claim 9, wherein the second hydrogen permeable membrane is formed with a PVD method, a CVD method, a sputtering method, a plating method or a sol-gel method.
